(19) United States
(12) Patent Application Publication
(10) Pub. No.: US 2022/0178969 A1
(43) Pub. Date: Jun. 9, 2022

(54) PROBE DEVICE AND METHOD OF ASSEMBLING THE SAME

(71) Applicant: STAR TECHNOLOGIES, INC., Hsinchu City (TW)

(72) Inventors: Choon Leong LOU, HSINCHU CITY (TW); TIEN-CHIA LI, ZHUBEI CITY (TW)

(21) Appl. No.: 17/111,036

(22) Filed: Dec. 3, 2020

(51) Int. Cl. G01R 1/073; G01R 1/067; G01R 31/28

(52) U.S. Cl. CPC G01R 1/07342; G01R 31/2886; G01R 1/06761

(57) ABSTRACT

A probe device includes a substrate, a holder, a plurality of test probes and a plurality of insulative skin layers. The substrate is provided with a conductive trace and the holder is disposed on the substrate. The test probes are oriented at an angle relative to the substrate, penetrating through the holder and electrically connected to the conductive trace. The insulative skin layer radially surrounds the test probe and contacts the test probe.

### TECHNICAL FIELD

The present disclosure relates to a probe device and a method of assembling the same, and more particularly, to a probe card that includes multiple test probes coated with insulative skin layer and a method of assembling the same.

### DISCUSSION OF THE BACKGROUND

Integrated circuits are manufactured and tested in wafer form before being diced from the wafer and mounted in packages or modules. Wafer-level integrated circuit testing is a critical part of the integrated circuit manufacturing process and identifies integrated circuits that do not function properly and provides feedback for improving product design and reducing manufacturing cost.

Conventional wafer integrated circuit testing uses probe cards to provide an electrical path between a test machine and electrical pads on integrated circuits in wafer form. Probe cards generally have probe tips that match the size and density of the electrical pads on an integrated circuit and conductive patterns that provide fan-out of electrical signals from the high-density probes to the lower-density connectors on the much larger printed circuit boards that interface to the IC tester.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a probe device. The probe device includes a substrate, a holder, a plurality of test probes and a plurality of insulative skin layers. The substrate is provided with a conductive trace. The holder is disposed on the substrate. The test probes are oriented at an angle relative to the substrate and penetrate through the holder, wherein the test probes are electrically connected to the conductive trace. The insulative skin layer surrounds the test probe radially. In addition, the insulative skin layer contacts the test probe.

In some embodiments, the test probe includes an intermediate portion gripped by the holder, a tail extending from one end of the intermediate portion and contacting the substrate or the conductive trace, a head extending from the other end of the intermediate portion, and a tip connected to the head.

In some embodiments, the holder comprises a first surface distal from the substrate and a second surface opposite to the first surface and attached to the substrate, and the first surface and the second surface are inclined at different angles with respect to the test probe.

In some embodiments, the first surface of the holder is parallel to the test probe.

In some embodiments, side surfaces of the holder and the substrate facing the head are coplanar.

In some embodiments, the head and the tip are cantilevered from the holder.

In some embodiments, the probe device further includes a supporter sandwiched between the substrate and the holder.

In some embodiments, the probe device further includes an adhesive between the holder and the supporter.

In some embodiments, a projection of the holder on the substrate is equal to or greater than a projection of the supporter on the substrate.

Another aspect of the present disclosure provides a method of assembling a probe device. The method includes steps of providing a plurality of test probes; forming a plurality of insulative skin layer on portions of the test probes; forming a holder to grip the portions of the test probe; disposing the holder with the test probes on a substrate; and electrically connecting the test probes to a conductive trace placed on the substrate.

In some embodiments, the insulative skin layer at least contacts the portion of the test probe between the conductive trace and the holder.

In some embodiments, tails of the test probes connect to the conductive trace by a solder material.

In some embodiments, the method further includes mounting a supporter on the substrate, wherein the holder and the test probes with the insulative skin layer inset therein is positioned on the supporter.

In some embodiments, the insulative skin layers are formed on the portions of the test probes using a coating process, a plating process or an oxidation process.

With the above-mentioned configurations of the probe device, the test voltage provided from a test machine to a DUT can be effectively increased.

With the above-mentioned configurations of the probe device, the issue of particulates, dirt, solder flux, contaminants, and so forth, resulting in high leakage current, lowered insulation, and defects created in wafer testing can be removed.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a cross-sectional view of a comparative probe device.

FIG. 2 is a cross-sectional view of a sleeve and a tail of a test prove of the comparative prove device.

FIG. 3 is a top view of a probe device in accordance with some embodiments of the present disclosure.

FIG. 4 is a cross-sectional view taken along the line A-A illustrated in FIG. 3.

FIG. 5 is a cross-sectional view taken along the line B-B illustrated in FIG. 3.

FIG. 6 is a flow diagram illustrating a method of assembling a probe device in accordance with some embodiments of the present disclosure.

FIG. 7 is a top view of a probe device in accordance with some embodiments of the present disclosure.

FIG. 8 is a cross-sectional view taken along the line C-C illustrated in FIG. 7.

FIG. 9 is a flow diagram illustrating a method of assembling a probe device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

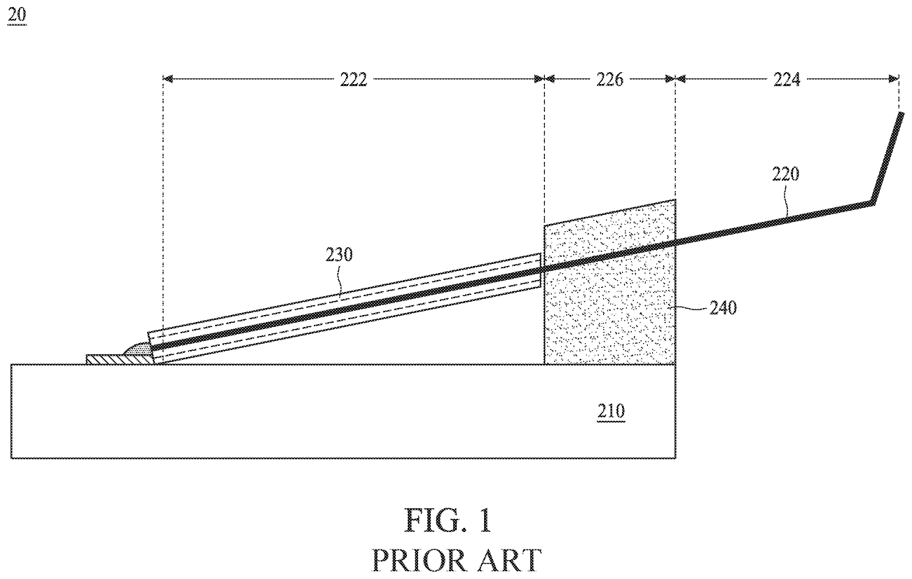

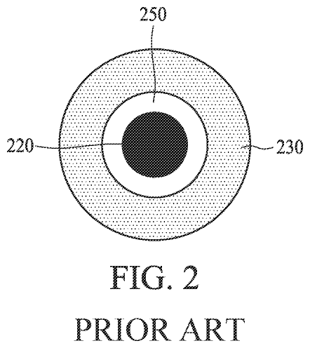

FIG. 1 is a cross-sectional view of a comparative probe device, and FIG. 2 is a cross-sectional view of a sleeve and a tail of a test probe of the comparative probe device. Referring to FIGS. 1 and 2, the probe device 20 includes a circuit board 210, a plurality of test probes 220, a plurality of sleeves 230 surrounding portions of the test probes 220, a holder 240 mounted on the circuit board 210 and used for orienting the test probes 230. Each sleeve 230, covering a portion of the test probe 220, is separated from the respective test probe 220 by an air gap 250.

The test probes 220 are used for transmitting signals from a test machine and a device under test (DUT). Each test probe 220 includes a tail 222, a head 224 and an intermediate portion 226 between the tail 222 and the head 224 for connecting the tail 222 to the head 224. An end of the tail 222 is mounted on the circuit board 210 electrically coupled to the test machine, and the intermediate portion 226 is gripped by the holder 240. Generally, the air gap 250 is created due to the sleeve 230, surrounding the tail 222 of the test probe 220, has a diameter much greater than a diameter of the test probe 220. The loose sleeves 230 cannot prevent the dirt and particulates, for leakage issue and high voltage breakdown, from falling on the tail 222 of the test probe 220.

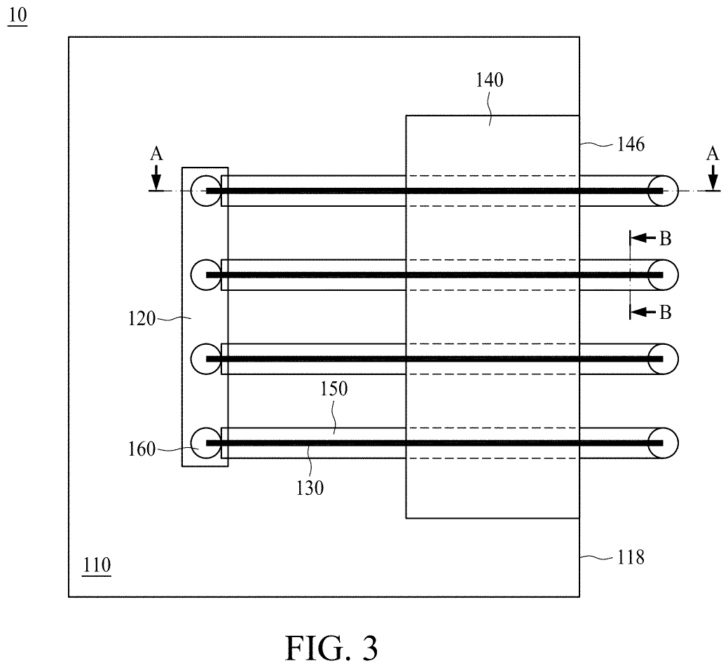

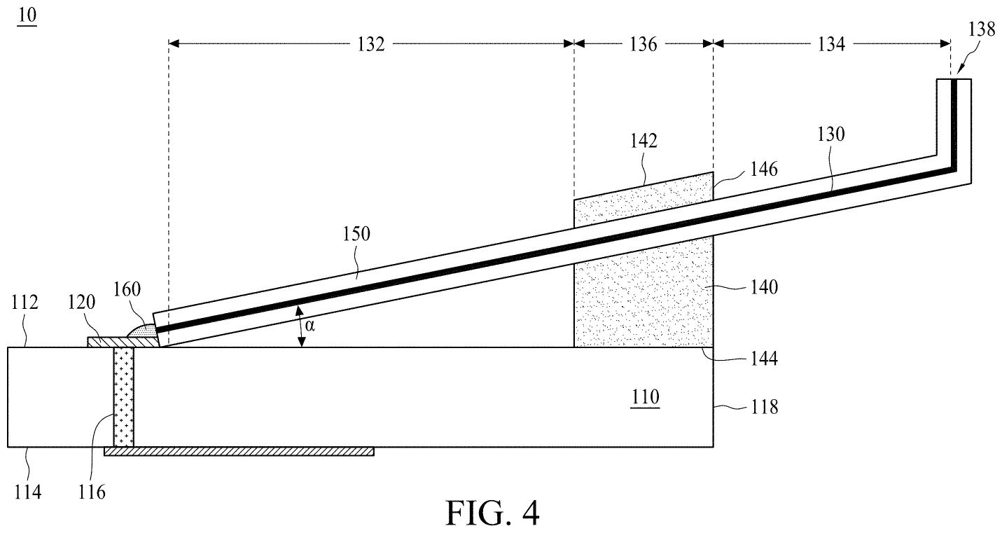

FIG. 3 is a top view of a probe device 10 in accordance with some embodiments of the present disclosure, and FIG. 4 is a cross-sectional view taken along the line A-A illustrated in FIG. 3. Referring to FIGS. 3 and 4, the probe device 10 is a cantilever probe card and includes a substrate 110 provided with at least one conductive trace 120, a plurality of test probes 130 oriented at an angle α relative to the substrate 110, a holder 140 disposed on the substrate 110 for positioning the test probes 130, and a plurality of insulative skin layer 150 enclosing the test probes 130 radially, thereby preventing electrical leakage and short circuit from the two adjacent test probes 130.

The conductive trace 120 on the substrate 110 is adapted to be electrically connected to a test machine (not shown), which is controllable to provide test signals to the probe device 10. In some embodiments, the substrate 110 includes a front surface 112 and the back surface 114 opposite to the front surface 112, and the conductive trace 120 can be placed on the front surface 112 and/or the back surface 114 for routing signals between the test probes 130 and the test machine. In some embodiments, the substrate 110 may further includes one or more vias 116 for electrically connecting the conductive trace 120 placed on the front surface 112 to the conductive trace 120 placed on the back surface 114 or embedded in the substrate 110. In some embodiments, the substrate 110 may be made of insulating material, such as polyimide, perylene, and epoxy-glass composite material. In some embodiments, the substrate 110 may be a flame retardant 4 (FR4) substrate. In some embodiments, the conductive trace 120 may be made of copper, gold, nickel, aluminum, palladium, tin, a combinations thereof or alloys thereof.

The test probes 130 are arranged according to requirements and used for conducting the signals provided from the test machine and through the conductive trace 120 to a DUT (not shown), such as a semiconductor wafer, a system-on-chip integrated circuit or a digital and/or analog integrated circuit. In some embodiments, the test probes 130 are also used for transmitting the signals outputted from the DUT to the test machine; the test machine can determine whether the DUT is operating properly based on the signals provided by the test machine or the signals outputted from the DUT.

In some embodiments, the test probes 130 are parallel to each other and arranged at specific intervals. In some embodiments, the test probes 130 are aligned on the substrate 110 at a nearly-constant interval. In alternative embodiments, the test probes 130 may be arranged in a radial manner.

The test probe 130 can include a tail 132 proximate to the substrate 110, a head 134 distal from the tail 132, an intermediate portion 136 sandwiched between the tail 132 and the head 134 and gripped by the holder 140, and a tip 138 connected to the head 134. In some embodiments, the head 134 and the intermediate portion 136 are substantially aligned with the tail 132; the tip 138 is angularly connected to an end of the head 134 and configured to contact the DUT. In some embodiments, the tail 132, the head 134, the intermediate portion 136 and the tip 138 are integrally formed and made of conductive material. In some embodiments, an end of the tail 132 is electrically connected to the conductive trace 120 by a solder material 160.

The holder 140 securing the test probes 130 on the substrate 110 is made of insulating material, such as curable epoxy resin. In some embodiments, the test probe 130 is positioned in the holder 140 before the holder 140 is mounted on the substrate 110. In some embodiments, the holder 140 includes a first surface 142 distal from the substrate 110 and a second surface 144 opposite to the first surface 142 and attached to the substrate 110, and the first surface 142 and the second surface 144 are inclined at different angles with respect to the test probe 130. In some embodiments, the first surface 142 is parallel to the test probes 130, and the second surface 144 is parallel to the front surface 112 of the substrate 110. In other words, a distance between the first surface 142 and the test probes 130, when viewed in a cross-sectional view, is constant across the first surface 142.

The holder 140 further includes a side surface 146 adjacent to the first surface 142 and the second surface 144 and facing the tip 138; the side surface 146 of the holder 140 is coplanar with a side surface 118 of the substrate 110 facing the tip 138, wherein the side surface 116 of the substrate 110 is adjacent to the front surface 112 and the back surface 114 thereof. In such configuration, the tail 132 and the intermediate portion 136 are disposed above the substrate 110, and the head 134 and the tip 138 are cantilevered from the holder 140.

The insulative skin layer 150 completely encases the test probe 130; in other words, the tail 132, the head 134, the intermediate portion 136 and the tip 138 are surrounded by the insulative skin layer 150. In some embodiments, the insulative sleeve 150 is attached to the test probe 130, as shown in FIG. 3. In other words, there is no air gap between the insulative skin layer 150 and the test probe 130. In some embodiments, the insulative skin layer 150 can be made of transparent insulative material to facilitate observing whether the test probe 130 is fractured. In some embodiments, the insulative skin layer 150 can be made of polymer to reduce or prevent electrical leakage from the head 134 to the adjacent head(s) 134. The insulative skin layer 150 can also prevent short circuit. In some embodiments, the insulative skin layer 150 may be formed using a coating process or a plating process. In some embodiments, the insulative skin layer 150 can be formed by oxidizing an external layer or surface of test probes 130 (i.e., the insulative skin layer 150 is formed using an oxidation process). In general, the dielectric breakdown, that occurs when the electrical field becomes high enough to cause some portion of a dielectric to abruptly switch from being an electrical insulator to a partial conductor, of air (i.e., the air dielectric breakdown) is about 3.3V/μm. Thus, in the probe device including bare test probes (i.e., without coating the insulative skin layer 150), the test voltage provided by the test machine and conducted to the DUT through the bare test probes must be less than 3.3V when a distance between the adjacent bare test proves is 100 μm. Electrostatic arcing may be induced if the test voltage conducted by the bare test probes spaced 100 μm apart is greater than 3.3V. In the present disclosure, the insulative skin layer 150, coating the test probes 130, can have the dielectric breakdown greater than that of the air, so that the test voltage provided by the test machine and conducted to the DUT through the test probes 130 can be increased. Hence, the probe device 10 of the present disclosure can be applied to electrostatic discharge (ESD) testing.

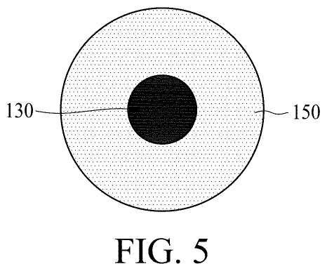

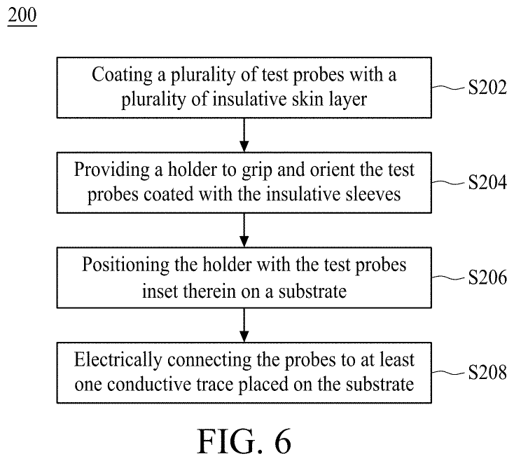

FIG. 6 is a flow diagram illustrating a method 200 of assembling the probe device 10 as shown in FIGS. 3, 4 and 5, in accordance with some embodiments of the present disclosure. Referring to FIGS. 4 and 6, the method 200 begins with an operation S202, in which a plurality of test probes 130 are respectively coated with a plurality of insulative skin layer 150. The method 200 proceeds to an operation S204, in which a holder 140 is provided to grip and orient the test probes 130 coated with the insulative skin layer 150, wherein the holder 140 grips intermediate portions 136 of the test probes 130 and causes tails 132 extending from ends of the intermediate portions 136 and heads 134 extending from the other ends of the intermediate portions 136 to be disposed at different levels. The method 200 proceeds to an operation S206, in which the holder 140 with the test probes 130 inset therein is positioned on a substrate 110. Next, the method 200 proceeds to an operation S208, in which the tails 132 of the test probes 130 are electrically connected to a conductive trace 120 placed on the substrate 110.

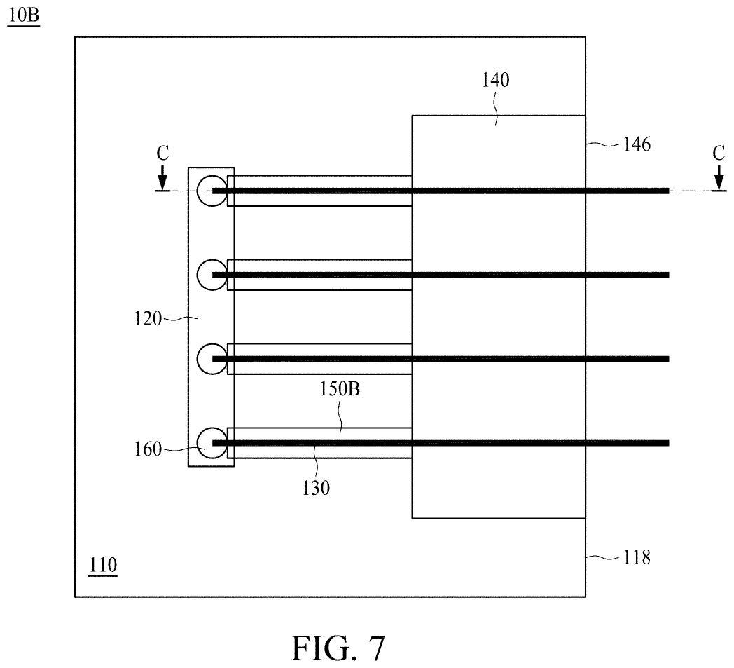

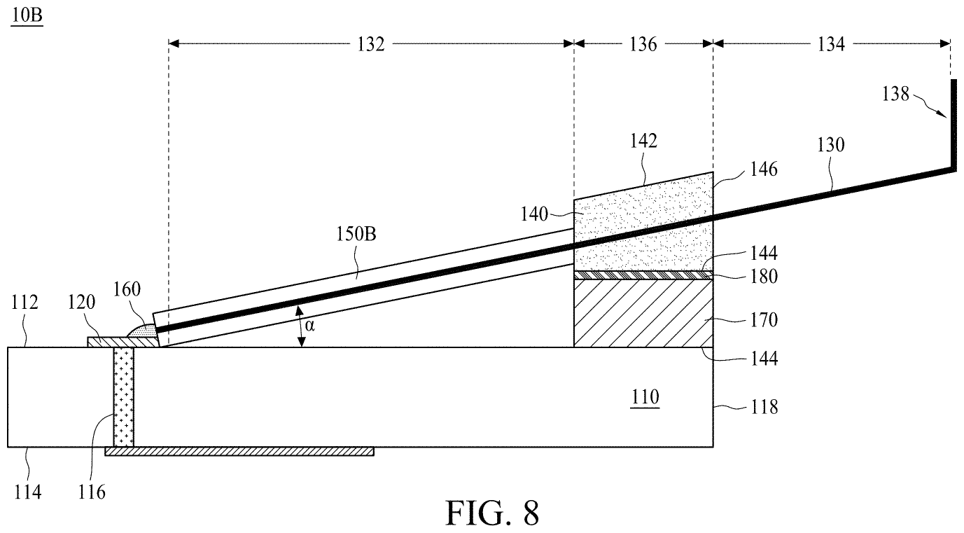

FIG. 7 is a top view of a probe device 10B in accordance with some embodiments of the present disclosure, and FIG. 8 is a cross-sectional view taken along the line C-C illustrated in FIG. 8. Referring to FIGS. 7 and 8, the probe device 10B includes a substrate 110 provided with at least one conductive trace 120, a plurality of test probes 130 obliquely oriented on the substrate 110, a holder 140 positioned on the substrate 110 and gripping portions of the test probes 130, a plurality of insulative skin layers 150 surrounding another portions of the test probes 130, and a supporter 170 sandwiched between the substrate 110 and the holder 140.

The holder 140 can have a trapezoidal cross section, and the supporter 170 can have a rectangular cross section. In some embodiments, the holder 140 includes a first surface 142 distal from the substrate 110 and a second surface 144 opposite to the first surface 142 and close to the substrate 110, and an area of the second surface 144 is substantially equal to an area of the substrate 110 occupied by the supporter 170. In some embodiments, a projection of the holder 140 on the substrate 110 is equal to a projection of the supporter 170 on the substrate 110. In some embodiments, the supporter 170 can be made of ceramic. The probe device 10A may further include an adhesive 180 between the holder 140 and the supporter 170 to affix the holder 140 to the supporter 170. In some embodiments, the adhesive 180 can be curable epoxy resin.

In some embodiments, the conductive trace 120 is placed on a front surface 112 of the substrate 110, wherein the supporter 170 is mounted on the front surface 112. In some embodiments, the test probe 130 includes a tail 132 where the conductive trace 120 is connected, wherein a solder material 160 is disposed between the conductive trace 120 and the tail 132 to electrically connect the conductive trace 120 to the test probe 130. In some embodiments, the test probe 130 further includes an intermediate portion 136 connected to the tail 132 and gripped by the holder 140 and a head 134 distal from the tail 132 and connected to the intermediate portion 136, wherein the head 134 is a cantilever. In some embodiments, the test probe 130 can also include a tip 138 vertically extending from the head 134. The holder 140 grips the intermediate portions of the test probes 130, and the insulative skin layers 150 surrounds and contact the tails 132 of the test probes 130, and the head 134 and the intermediate portion 136 are exposed to the insulative skin layer 150B. In some embodiments, the holder 140 contacts the intermediate portion 136, and the insulative skin layer 150B may contact the holder 140.

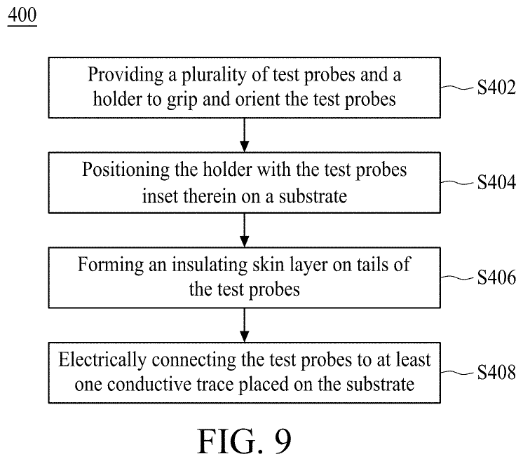

FIG. 9 is a flow diagram illustrating a method 400 of assembling the probe device 10B as shown in FIGS. 7 and 8, in accordance with some embodiments of the present disclosure. referring to FIGS. 8 and 9, the method 400 begins with an operation S402, in which a plurality of test probes 130 and a holder 140 are provided, wherein the holder 140 grips intermediate portions 136 of the test probes 130 and causes tails 132 extending from ends of the intermediate portions 136 and heads 134 extending from the other ends of the intermediate portions 136 to be disposed at different levels. The method 400 proceeds to an operation S404, in which the holder 140 with the test probes 130 inset therein is positioned on a substrate 110. The method 400 proceeds to an operation S406, in which a plurality of insulative skin layer 150B are formed, and the tails 132 of the test probes 130 are respectively coated with the insulative skin layer 150B. Next, the method 200 proceeds to an operation S408, in which the tails 132 of the test probes 130 are electrically connected to a conductive trace 120 placed on the substrate 110. In some embodiments, the insulative skin layer 150B may be formed on the tail 132 of the test probes 130 before assembling the test probes 130 to the holder 140. In alternative embodiments, the insulative skin layer 150B may be formed on the tail 132 of the test probes 130 after the test probes 130 and the holder 140 are assembled but the positioning of the holder 140 on the substrate 110.

One aspect of the present disclosure provides a probe card. The probe device includes a substrate, a holder, a plurality of test probes and a plurality of insulative skin layers. The substrate is provided with a conductive trace and the holder is disposed on the substrate. The test probes are oriented at an angle relative to the substrate and penetrate through the holder, wherein the test probe is electrically connected to the conductive trace. The insulative skin layer surrounds and contacts the test probe radially.

One aspect of the present disclosure provides a method of assembling a probe device. The method includes steps of providing a plurality of test probes and forming into a plurality of insulative skin layer on portions of the test probes; forming a holder to grip portions of the test probes; disposing the holder with the test probes on a substrate; and electrically connecting the test probes to a conductive trace placed on the substrate.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods and steps.

1. A probe device, comprising:
a substrate provided with a conductive trace;
a holder disposed on the substrate;
a plurality of test probes oriented at an angle relative to the substrate and penetrating through the holder, wherein the test probe is electrically connected to the conductive trace; and
a plurality of insulative skin layers radially surrounding the test probes and contacting the test probes, wherein the insulative skin completely encases the test probe.

2. The probe device of claim 1, wherein the test probe comprises an intermediate portion gripped by the holder, a tail extending from one end of the intermediate portion and contacting the conductive trace, a head extending from the other end of the intermediate portion, and a tip connected to the head, the intermediate portion, the tail, the head, and the tip are surrounded by the insulative skin layer.

3. The probe device of claim 2, wherein the holder comprises a first surface distal from the substrate and a second surface opposite to the first surface and attached to the substrate, and the first surface and the second surface are inclined at different angles with respect to the test probe.

4. The probe device of claim 3, wherein the first surface of the holder is parallel to the test probe.

5. The probe of claim 2, wherein side surfaces of the holder and the substrate facing the head are coplanar.

6. The probe of claim 2, wherein the head and the tip are cantilevered form the holder.

7. The probe device of claim 1, further comprising a supporter sandwiched between the substrate and the holder.

8. The probe device of claim 7, further comprising an adhesive between the holder and the supporter.

9. The probe device of claim 7, wherein a projection of the holder on the substrate is equal to or greater than a projection of the supporter on the substrate.

10. A method of assembling a probe device, comprising:
providing a plurality of test probes;
forming a plurality of insulative skin layers on the test probes, wherein the insulative skin layer completely encases the test probe;
providing a holder to grip the portions of the test probes;
disposing the holder with the test probes on a substrate; and
electrically connecting the test probes to a conductive trace placed on the substrate.

11. The method of claim 10, wherein the insulative skin layer contacts of the test probe.

12. The method of claim 10, wherein the holder grips the test probes obliquely.

13. The method of claim 10, wherein tails of the test probes connect to the conductive trace by a solder material.

14. The method of claim 10, further comprising mounting a supporter on the substrate, wherein the holder and the test probes with the insulative skin layer inset therein is positioned on the supporter.

15. The method of claim 10, wherein the insulative skin layers are formed on the portions of the test probes using a coating process, a plating process or an oxidation process.
